(19) United States
(12) Patent Application Publication
(10) Pub. No.: US 2007/0183489 A1
(43) Pub. Date: Aug. 9, 2007

(54) Apparatus for decoding a signal and method thereof and a trellis coded modulation decoder and method thereof

(75) Inventor: Sergey Zhidkov, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/348,460

(22) Filed: Feb. 7, 2006

(51) Int. Cl. H03H 7/30; H04L 23/02

(52) U.S. Cl. 375/229; 375/265

(57) ABSTRACT

An apparatus for decoding a signal and method thereof and a TCM decoder and method thereof. The TCM decoder may calculate a branch metric based on path metrics received from a plurality of other TCM decoders. The TCM decoder may be included within a joint TCM decoder which may be included within the apparatus. In an example, the apparatus may be a time-division multiplexed trellis-coded modulation (TDM-TCM) decoder. In another example, the apparatus may further include an equalizer feedback part.

### BACKGROUND OF THE INVENTION

1. Field of the Invention

Example embodiments of the present invention relate generally to an apparatus and method thereof and a trellis coded modulation (TCM) decoder and method thereof, and more particularly to an apparatus for decoding a signal and method thereof and a TCM decoder and method thereof.

2. Description of the Related Art

A trellis coded modulation (TCM) scheme may refer to a channel coding scheme having a higher coding gain in a bandwidth-limited channel. The TCM scheme may be implemented as a combination of a coding technique and a modulation technique. The TCM scheme may increase a power gain without a significant loss in bandwidth. In a receiver, a reception signal mixed with noise (e.g., including additive white Gaussian noise (AWGN)) may be decoded using a decoder that may perform a maximum likelihood decoding (MLD). In an example, the TCM scheme may provide a power gain in a range of 3˜6 dB or more in digital signal transmission channels with AWGN. The TCM scheme may be employed in a broad range of devices, such as high definition televisions (HDTVs).

A Viterbi algorithm may be used for decoding a TCM signal. The Viterbi algorithm may perform the MLD and may use a trellis diagram to reduce a number of calculations. The Viterbi algorithm may compare a reception signal with a path in each of a plurality of states. The Viterbi algorithm may generate a single, resultant path based on the comparisons. The comparisons may be repeated for each of the plurality of states along a time axis of the trellis diagram. Accordingly, a processing time required to execute the Viterbi algorithm may be based on the number of states, and not necessarily on a length of a transmission code sequence.

Inter-symbol interference (ISI) may be a common problem experienced in data transmission channels of digital communication systems. Conventional equalization techniques may be used to suppress the ISI communication channels. Examples of conventional equalization techniques include a maximum-likelihood sequence estimation (MLSE), a linear equalization (LE) and a decision-feedback equalization (DFE).

Conventional error correction techniques may be used to reduce errors due to thermal noise in AWGN environments. An example of an error correction technique may be a TCM error correction technique.

FIG. 1 illustrates a conventional demultiplexed TCM decoder. Referring to FIG. 1, the demultiplexed TCM decoder may include a plurality of TCM encoders 20/30/40/50 received from a deinterleaver 10. The TCM encoders 20/30/40/50 may output TCM encoded signals to an output port 60, which may select and output one of the plurality of TCM encoded signals to an ISI channel 70. The ISI channel 70 may transfer the selected TCM encoded signal to a receiver. The conventional demultiplexed TCM decoder of FIG. 1 may be employed in an Advanced Television Systems Committee (ATSC) digital TV broadcasting system (e.g., which may be accepted as a national standard in the United States, Canada and South Korea). A transmission scheme employed in accordance with the ATSC standard may be referred to as a time-division multiplexed trellis-coded modulation (TDM-TCM) scheme.

FIG. 2 is a schematic block diagram of a linear equalizer 210 and a demultiplexed TCM decoder 220. Referring to FIG. 2, the linear equalizer 210 may reduce ISI on received signals and the demultiplexed TCM decoder 220 may perform a decoding operation on the ISI reduced AWGN channels. The linear equalizer 210 may not be able to compensate for a distortion with respect to a channel having a spectral null where a frequency response C(f) at a given frequency in a channel bandwidth becomes null (e.g., approximately zero). If a gain of the linear equalizer 210 is increased so as to compensate for the spectral null, a noise level (e.g., an AWGN noise level) may increase along with the signal strength. This effect may be referred to as a “noise enhancement” phenomenon. Accordingly, it may be difficult to reduce noise in a channel having the spectral null.

FIG. 3 is a block diagram of a conventional feedback TCM decoder arrangement. Referring to FIG. 3, the feedback TCM decoder arrangement may include a feedforward filter 300, a slicer 310, a feedback filter 320 and the TCM decoder 220 described above with respect to FIG. 2. The feedforward filter 300 may output a signal to the slicer 310. The slicer 310 may reduce (e.g., remove) ISI associated with the received signal (e.g., a pre-ghost included in the received signal).

Referring to FIG. 3, the slicer 310 may be a hard decision device used as a decision unit of the feedback TCM decoder arrangement. For example, in a 8VSB system, the slicer 310 may be a decision device having values of 0, ±2, ±4 and ±6 so as to classify input symbols into symbols corresponding to normalized signal values of ±1, ±3, ±5 and ±7, respectively. The feedback filter 320 may receive the output of the slicer 310 to generate a feedback ISI estimate. The conventional feedback TCM decoder arrangement of FIG. 3 may cause an “error propagation” effect due to a higher decision error probability associated with the output of the slicer 310.

FIG. 4 is a block diagram illustrating another conventional feedback TCM decoder arrangement. The feedback TCM decoder arrangement of FIG. 4 may employ a reduced depth TCM decoding so as to reduce the error propagation effect. Referring to FIG. 4, unlike the feedback TCM decoder arrangement of FIG. 3, a TCM decoder 410 may be used as a decision device (e.g., as opposed to the slicer 310 of FIG. 3). The TCM decoder 410 may be more reliable than the slicer 310, which may accordingly reduce the error propagation effect.

The feedback TCM decoder arrangement of FIG. 4 may include a feedforward filter 400 having the same structure, operation and/or input/output (I/O) characteristics as the feedforward filter 300, with the feedforward filter 400 being configured to receive signals from the TCM decoder 410 instead of the slicer 310.

Referring to FIG. 4, the TCM decoder 410 may be a multiplexed decoder including v independent TCM decoders with decision data 430. The decision data 430 of the respective TCM decoders corresponding to the same decoding depth may be output to the feedback filter 420. The structure and operation of the TCM decoder 410 will be described in greater detail below with reference to FIG. 5.

Based on the decision data received from the TCM decoder 410, the feedback filter 420 may detect an error of a reception symbol, may calculate a value for compensating for the detected error, and may transfer the calculated value to the TCM decoder 410.

The feedback TCM decoder arrangement of FIG. 4 may experience the above-described error propagation effect. Further, the error propagation effect may worsen if a channel includes a shorter delayed ghost (e.g., an ISI component). In order to compensate for the shorter delayed ghost, the decoding depth of the TCM decoder may be reduced (e.g., to 0 or 1), which may accordingly reduce a reliability of the feedback TCM decoder arrangement.

FIG. 5 is a block diagram of the conventional TCM decoder 410 of FIG. 4. Referring to FIG. 5, the TCM decoder 410 may include a deinterleaver 510, a plurality of TCM decoders 520/530/540 and a plurality of output ports 550/560/570. The deinterleaver 510 may deinterleave interleaved or time-division multiplexed symbols received from a transmitter and may transfer the deinterleaved signals to the plurality of TCM decoders 520/530/540. The plurality of TCM decoders 520/530/540 may transfer trellis-decoded decision data to switches corresponding to a decoding depth (e.g., in a range between 0 and N). If the decoding depth is higher, a trace-back size may be increased to attain more accurate decision data.

Referring to FIG. 5, a performance of the conventional TCM decoder 410 may be improved by employing a parallel decision feedback scheme. However, the parallel decision feedback scheme used in the TDM-TCM system may only reduce the error propagation effect in limited cases. One such example scenario may be where ghost delays may be a multiple of v*T, where T may be a symbol duration and v may be the number of TCM encoders.

Since the TCM decoder may be more reliable than the slicer, an equalization scheme using the TCM decoder as the decision device may reduce an error propagation effect and/or improve an operation of the decoder. However, the TCM decoder of FIG. 4 may still undergo an error propagation effect when a channel introduces a shorter delayed ghost.

### SUMMARY OF THE INVENTION

An example embodiment of the present invention is directed to an apparatus for decoding a signal, including an equalizer feedback part generating at least one error signal based on feedback symbol decision values for at least one of a plurality of surviving paths, calculating rank information ranked based at least in part on an interference level, and equalizing a reception signal based at least in part on at least one of the feedback symbol decision values to generate a reception symbol and a joint TCM decoder including a plurality of TCM decoders, at least one of the plurality of TCM decoders calculating a branch metric based on the error signal, the reception symbol, the rank information and an operation of at least one other of the plurality of TCM decoders.

Another example embodiment of the present invention is directed to a method for decoding a signal, including equalizing a reception signal to generate a reception symbol based on decision data associated with a previous reception symbol, calculating error signals associated with the decision data based on a most probable surviving path of the previous symbol and decision data associated with remaining surviving paths and calculating branch metrics based on the reception symbol, the error signals, rank information associated with a plurality of TCM decoders, and path metrics for each of the plurality of TCM decoders.

Another example embodiment of the present invention is directed to a method for decoding a signal, including calculating a main equalizer output signal and an error signal based on a reception signal and a decision value of a previous reception symbol and calculating branch metrics of an active TCM decoder based on the main equalizer output signal, the error signal, and path metrics associated surviving paths of a plurality of inactive TCM decoders.

Another example embodiment of the present invention is directed to a method of branch metric calculation, including calculating a branch metric based at least in part on a plurality of received path metrics.

Another example embodiment of the present invention is directed to a TCM decoder, including a branch metric unit calculating a branch metric based at least in part on a received plurality of path metrics.

### BRIEF DESCRIPTION OF THE DRAWINGS

The accompanying drawings are included to provide a further understanding of example embodiments of the invention, and are incorporated in and constitute a part of this specification. The drawings illustrate example embodiments of the present invention and, together with the description, serve to explain principles of the present invention.

FIG. 1 illustrates a conventional demultiplexed trellis coded modulation (TCM) decoder.

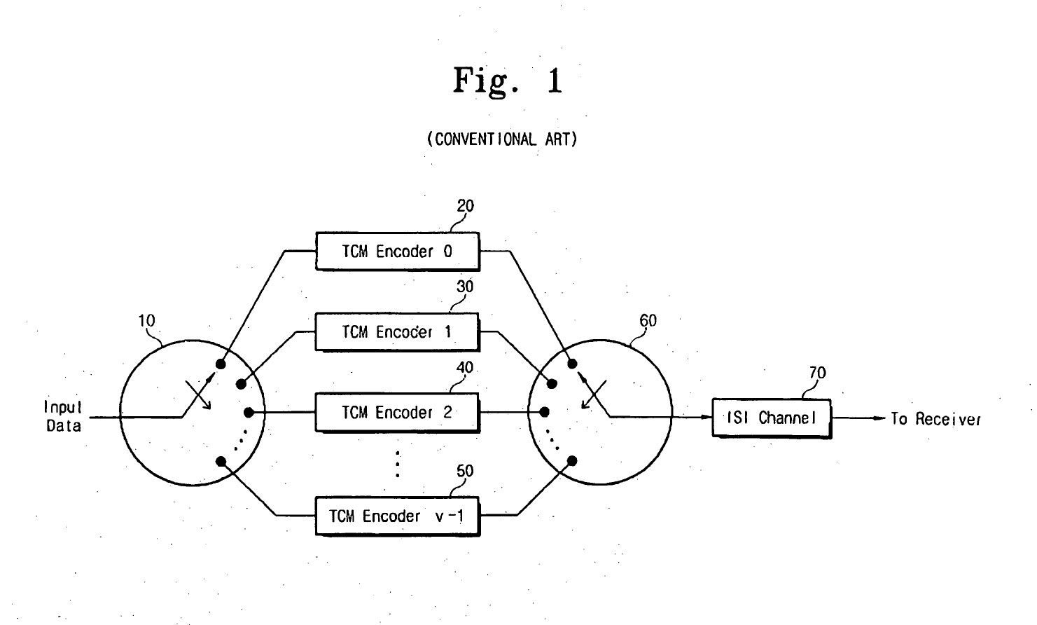

FIG. 2 is a schematic block diagram of a linear equalizer and a demultiplexed TCM decoder.

FIG. 3 is a block diagram of a conventional feedback TCM decoder arrangement.

FIG. 4 is a block diagram illustrating another conventional feedback TCM decoder arrangement.

FIG. 5 is a block diagram of the conventional TCM decoder of FIG. 4.

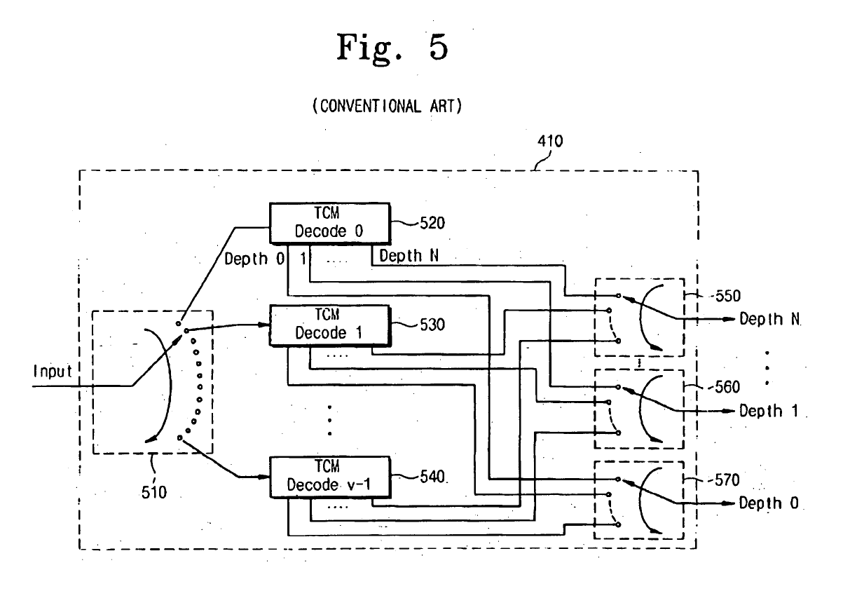

FIG. 6 is a block diagram of a time division multiplex (TDM)-TCM decoder according to an example embodiment of the present invention.

FIG. 7 is a block diagram illustrating a joint TCM decoder according to another example embodiment of the present invention.

FIG. 8 is block diagram illustrating a TCM decoder according to another example embodiment of the present invention.

FIG. 9 is a block diagram illustrating a branch metric unit according to another example embodiment of the present invention.

FIG. 10 is a block diagram illustrating a one-stage branch metric calculator according to another example embodiment of the present invention.

FIG. 11 is a flowchart illustrating a branch metric calculation process according to another example embodiment of the present invention.

FIG. 12 illustrates a graph of bit error rate (BER) performance for a plurality of equalization schemes according to another example embodiment of the present invention.

FIG. 13 illustrates a graph of BER performance for a plurality of equalization schemes according to another example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”“includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Hereinafter, the following denotations may be used:
rₙ may denote a feedforward filter output for an n-th symbol;
bⱼ(j=1,2,3, . . . , K) may denote feedback filter coefficients;
d^{(best)} may denote decisions associated with a “best” (e.g., more probable) surviving path;
d⁽ⁱ⁾(i=1,2, . . . ,m) may denote decisions associated with an i-th surviving path, and m may denote a number of trellis encoder states; and
v may denote a number of multiplexed trellis coded modulation (TCM) encoders and/or TCM decoders.

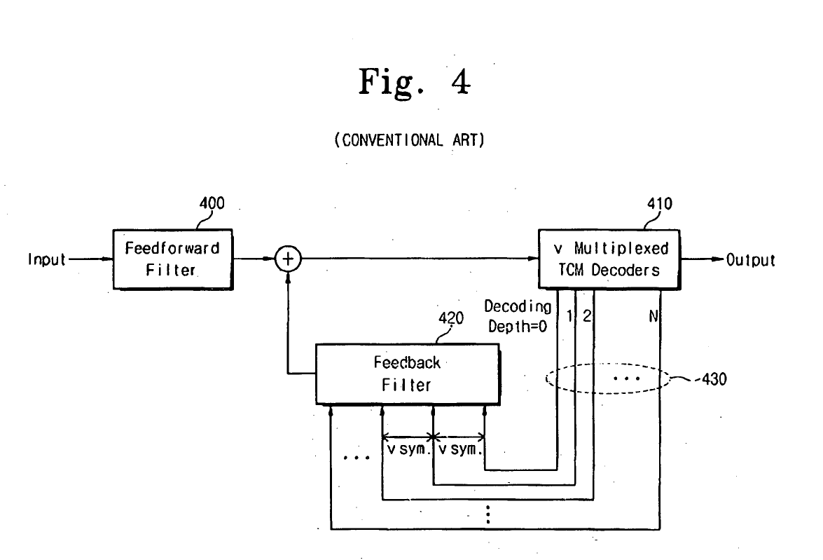

The output of the TCM decoders 410 of FIG. 4 may be expressed by

$${x}_{n}^{( best )} = {r}_{n} + {\sum }_{j = 1}^{K} {b}_{j} {d}_{n - j}^{( best )} \qquad Equation 1$$

As can be seen from Equation 1, the equalizer output may be supplied to independent TCM decoders (FIG. 4). In other words, in conventional decoding methods, the decoder may be represented as a set of v identical independent TCM decoders that may not use path metric and/or surviving sequence information associated with other TCM decoders.

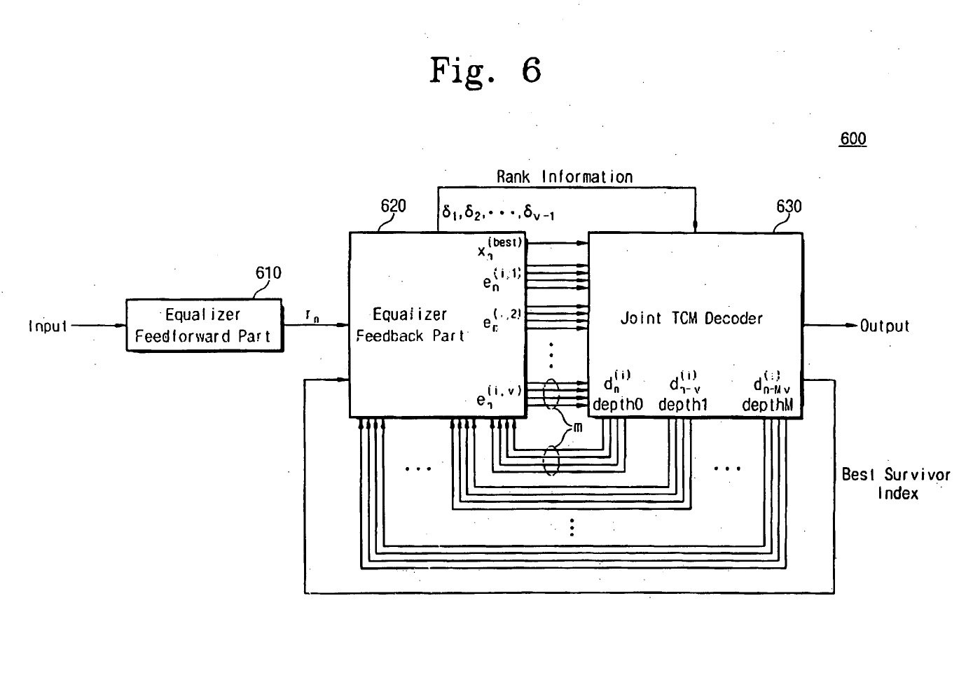

FIG. 6 is a block diagram of a TDM-TCM decoder 600 according to an example embodiment of the present invention.

In the example embodiment of FIG. 6, the TDM-TCM decoder 600 according may use a joint TCM decoding scheme by taking into account path metrics and decisions associated with every survivor of a plurality of TCM decoders during a calculation of a branch metric. The TDM-TCM decoder 600 may select surviving sequences for an active TCM decoder (e.g., one of the plurality of TCM decoders). The TDM-TCM decoder 600 may include an equalizer feedforward part 610 which may function as a feedforward filter, an equalizer feedback part 620 which may function as a feedback filter, and a joint TCM decoder 630 that may perform decoding and demultiplexing operations on trellis codes.

In the example embodiment of FIG. 6, the equalizer feedforward part 610 may be a general feedforward filter. The equalizer feedforward part 600 may be used in one or more communication systems so as to reduce an effect of a pre-ghost among the ISI components contained in a received symbol. As shown in FIG. 6, the equalizer feedforward part 610 may reduce a pre-ghost contained in an input signal to output a received symbol rₙ. It is understood that the equalizer feedforward part 610 may perform functions other than (e.g., in place of or in addition to) pre-ghost-reduction.

In the example embodiment of FIG. 6, the equalizer feedback part 620 may receive (e.g., through a feedback loop) a best survivor index indicating a most probable surviving path and decisions d⁽ⁱ⁾ based on surviving paths of TCM decoders (not shown) in the joint TCM decoder 630. In an example, an equalizer (not shown) of the equalizer feedback part 620 may have the same structure and operation as the feedback filter 420 described above with respect to FIG. 4. Accordingly, the equalizer of the equalizer feedback part 620 may add a weight to a symbol decision value corresponding to the most probable surviving path (e.g., a best survivor) to output error-corrected data. Such a process may be equivalent to a (best) general equalizer scheme, which may correspond to the output signal xₙ^{(best)} of Equation 1. The output signal xₙ^{(best)} of Equation 1 may be used for updating coefficients of an equalizer and a decoding algorithm. An updating of such coefficients will be readily understood by one skilled in the art, and as such a detailed description thereof will be omitted for the sake of brevity.

In the example embodiment of FIG. 6, in response to the m-th received symbols rₙ, the equalizer feedback part 620 may generate m×v additional error signals eₙ^{(j,k)}, which may be expressed as

$${e}_{n}^{( i , k )} = {\sum }_{t = 0}^{{}^{*} K / v +} {b}_{N + k} ( {d}_{n - tv - k}^{i} - {d}_{n - tv - k}^{( best )} ) ; \\ ( k = 1 , 2 , … , v ; i = 0 , 1 , … , m - 1 ) \qquad Equation 2$$

where *K/v+ may denote maximum integer not exceeding K/v.

It will readily understood by those skilled in the art that the conventional parallel-decision feedback scheme may generate m outputs which may be expressed as
xₙ⁽ⁱ⁾=xₙ^{(best)}+eₙ^{(i,v)} Equation 3

In the example embodiment of FIG. 6, the main equalizer output xₙ^{(best)} and the additional error signals eₙ^{(i,k)} n may be fed to the joint TCM decoder 630. The equalizer feedback part 620 may rank the TCM decoders of the joint TCM decoder 630 based on an ISI intensity and may transfer the resultant rank information to the joint TCM decoder 630. In an example, the ISI intensity may be estimated using a magnitude of the feedback filter coefficients. The rank information may be expressed as δ₁, δ₂, . . . , δᵥ₋₁. For example, the TCM decoder corresponding to the strongest ISI component may have an associated rank index of δ₁, and the TCM decoder corresponding to the weakest ISI component may have an associated rank index of δᵥ₋₁. In an example, the rank information may be calculated using

$${u}_{j} = {\sum }_{k = 1}^{{}^{*} K / v +} {w}_{k} {\vert {b}_{v ( k - 1 ) + j} \vert}^{2} \qquad Equation 4$$

where wₖ may denote weighting coefficients (e.g., w₁≧w₂≧w₃≧ . . . ≧wᵥ₋₁≧0) and δₜ may denote the rank index of reordered elements of uⱼ.

In the example embodiment of FIG. 6, the joint TCM decoder 630 may receive the rank information and the output xₙ⁽ⁱ⁾ from the equalizer feedback part 620 to calculate branch metrics (BMs) by using v dependent TCM decoders. The joint TCM decoder 630 may select the most probable path based on the calculated BMs and may analyze (e.g., trace-back) the selected path. The length of the trace-back operation may be referred to as a “decoding depth”. As the decoding depth increases, the error correction effect may increase. However, since a decoding delay and a system complexity may increase as the decoding depth increases, the system may take into account a trade-off between the decoding depth and the decoding delay and/or system complexity. The joint TCM decoder 630 may output symbol decisions and the best survivor indexes based on the trace-back operation results from the respective TCM decoders. At this point, the path metric Γ^{(i,k)} related to the surviving path of each of the plurality of TCM decoders may be calculated and stored (e.g., in memory). The calculated path metrics for each of the plurality of TCM decoders may be shared with the other TCM decoders, such that each TCM decoder may have knowledge of operations at each other TCM decoder. With respect to the path metric Γ^{(i,k)}, i may denote a surviving path index and k may denote a TCM decoder index.

In the example embodiment of FIG. 6, as discussed above, the equalizer feedback part 620 may generate the error signals eₙ^{(i,k)} from the symbol decision data d⁽ⁱ⁾ received from the joint TCM decoder 630 and may generate the rank information δ₁, δ₂, . . . , 67 ᵥ₋₁ based on the ISI intensity, the weighting coefficients wₖ and the equalizer filter coefficients bⱼ. The joint TCM decoder 630 may calculate the BMs and the symbol decisions on the basis of the rank information δ₁, δ₂, . . . , δᵥ₋₁, the output signals xₙ⁽ⁱ⁾ and the error signals eₙ^{(i,k)} received from the equalizer feedback part 620 and the surviving path metrics received from the plurality of TCM decoders.

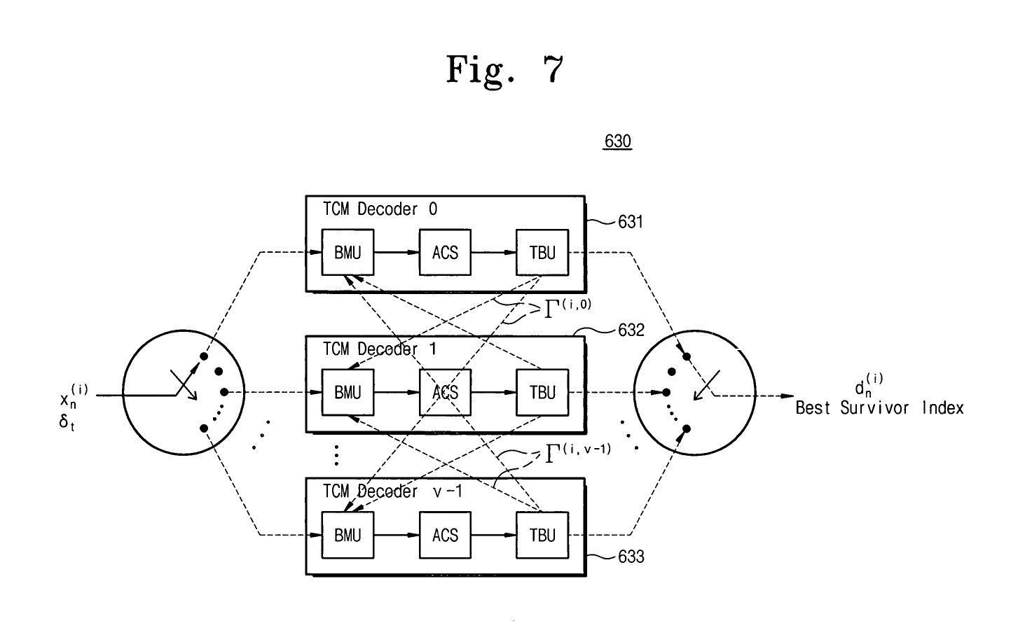

FIG. 7 is a block diagram illustrating the joint TCM decoder 630 of FIG. 6 according to another example embodiment of the present invention.

In the example embodiment of FIG. 7, the joint TCM decoder 630 may interleave signals received from the equalizer feedback part 620 and may transfer the interleaved signals to a plurality of TCM decoders 631, 632 and 633. Hereinafter, the TCM decoder 631 will be described as being representative of the operation at each of the plurality of TCM decoders 631, 632 and 633 (e.g., which may be representative of TCM decoders 0 to v−1).

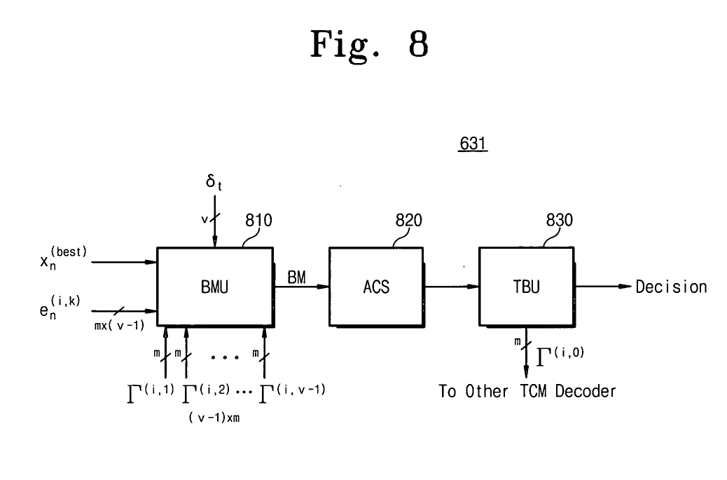

In the example embodiment of FIG. 7, upon reception of the interleaved signal, the TCM decoder 631 may receive the rank information δ₁, δ₂, . . . , δᵥ₋₁, the main equalizer output signals xₙ^{(best)} and the additional error signals eₙ^{(i,k)} from the equalizer feedback part 620. The TCM decoder 631 may thereby be considered the “active” TCM decoder. The TCM decoder 631 may also receive the path metrics Γ^{(i,k)} corresponding to the surviving paths from the remaining “inactive” TCM decoders 632 and 633. Accordingly, during a decoding operation (e.g., a calculation of the BMs), the TCM decoder 631 may calculate the BMs with information regarding the surviving paths of each of the plurality of TCM decoders. The BM calculation operation may thereafter be performed at other TCM decoders (e.g., TCM decoder 632) as the “active” status is transferred. Operational characteristics of the joint TCM decoder 630 may thereby be determined by a plurality of inter-dependent TCM decoders. The calculation of the BMs will be described later with greater detail with reference to FIGS. 8 through 11. The best survivor indexes and the symbol decision signals dₙ⁽ⁱ⁾ obtained by the interdependent BM calculation operations of the TCM decoders may be outputted through an output port of the joint TCM decoder 630.

FIG. 8 is block diagram illustrating the TCM decoder 631 of FIG. 7 according to another example embodiment of the present invention.

In the example embodiment of FIG. 8, the TCM decoder 631 may calculate a BM based on a signal received from the equalizer feedback part 620 and the path metric information from the remaining, inactive TCM decoders. The TCM decoder 631 may include a branch metric unit (BMU) 810, an add-compare-select (ACS) unit 820 and a trace-back unit (TBU) 830.

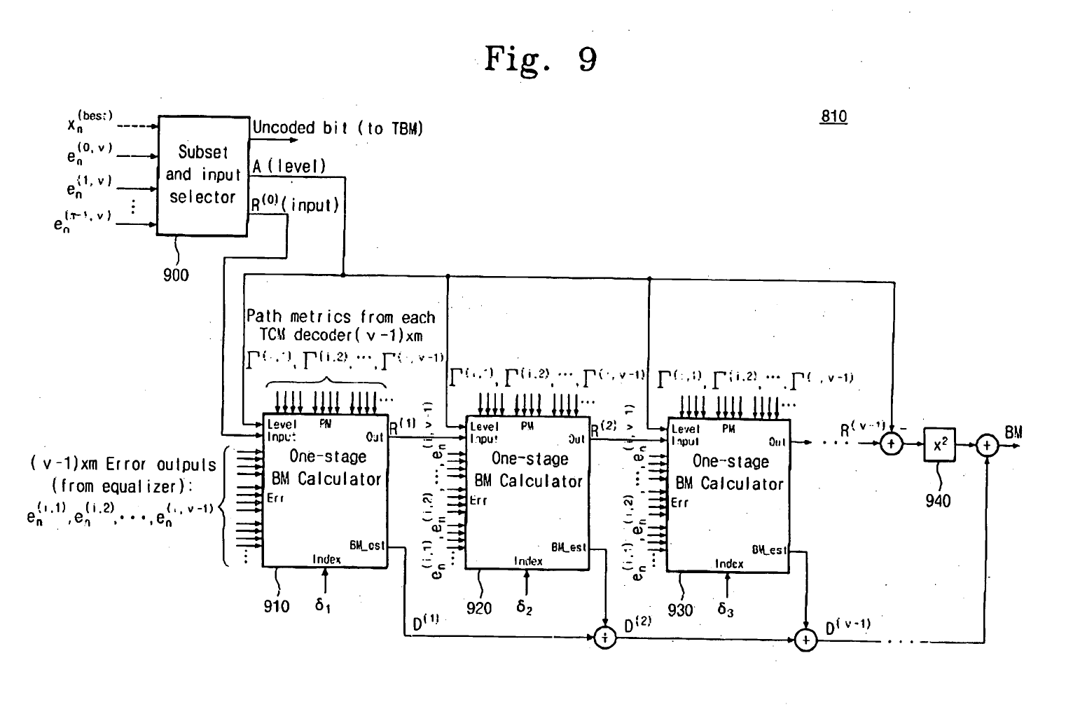

In the example embodiment of FIG. 8, the BMU 810 may receive the rank information δ₁, δ₂, . . . , δᵥ₋₁, the main equalizer output signals xₙ^{(best)} and the additional error signals eₙ^{(i,k)} from the equalizer feedback part 620. The BMU 810 may also receive the path metrics Γ^{(i,k)}˜Γ^{i,v-1} from the remaining inactive TCM decoders. The BMU 810 may use the above-described received information to calculate the BM. An example structure and operation of the BMU 810 will be described in greater detail later with respect to FIG. 9.

In the example embodiment of FIG. 8, the ACS unit 820 may receive the BM from the BMU 810 and may combine the received BM with a previously accumulated path metric to calculate a new path metric in each state. The ACS unit 820 may compare the calculated path metrics for the respective states to select a path having a reduced (e.g., minimum) path metric as a surviving path. The above-described update, compare and select operations may be repeated (e.g., each time a new BM may be received) to output a resultant “decision vector” to the TBU 830, the decision vector referring to the path information selected by the ACS unit 820. The previous state value may be determined based on the decision vector value and the current state value.

In the example embodiment of FIG. 8, the TBU 830 may trace back the path based on the received decision vectors to determine reception data. Although not illustrated in FIG. 8, the TBU 830 may include a trace-back memory (TBM) and/or trace-back logic (TBL). The TBU 830 may transfer a path metric Γ^{(i,0)} stored in the TBM to BMUs of the remaining interrelated TCM decoders so that the BMUs may use the stored path metric Γ^{(i,0}) for the respective BM calculations.

While the example embodiment of FIG. 8 has been above-described and illustrated as being directed to the TCM decoder 631 of FIG. 7, it is understood that the structure and function of the TCM decoder 631 as described/illustrated in FIG. 8 may be representative of one or more of the TCM decoders (e.g., TCM decoder 632, etc.) of FIG. 7.

FIG. 9 is a block diagram illustrating the BMU 810 of FIG. 8 according to another example embodiment of the present invention.

In the example embodiment of FIG. 9, the BMU 810 may calculate a BM based on the error signal received from the equalizer feedback part 620 and the surviving path metrics received from the plurality of TCM decoders 631, 632 and 633. The BMU 810 may include a subset and input selector 900, one-stage BM calculators 910, 920 and 930 and an absolute value squarer 940.

In the example embodiment of FIG. 9, the subset and input selector 900 may receive the additional error signal eₙ^{(i,v)} corresponding to the TCM decoder 631 and the main equalizer output signal xₙ^{(best)} among the output signals of the equalizer feedback part 620. The subset and input selector 900 may output uncoded bits of the received symbol to the TBM of the TBU 830, may select and output a reference level A corresponding to each state in a trellis diagram, and may calculate and output an initial input signal R(0) to the one-stage BM calculator 910. The initial input signal R(0) may be given as
R⁽⁰⁾=xₙ^{(best)}+eₙ^{(i,v)} Equation 5

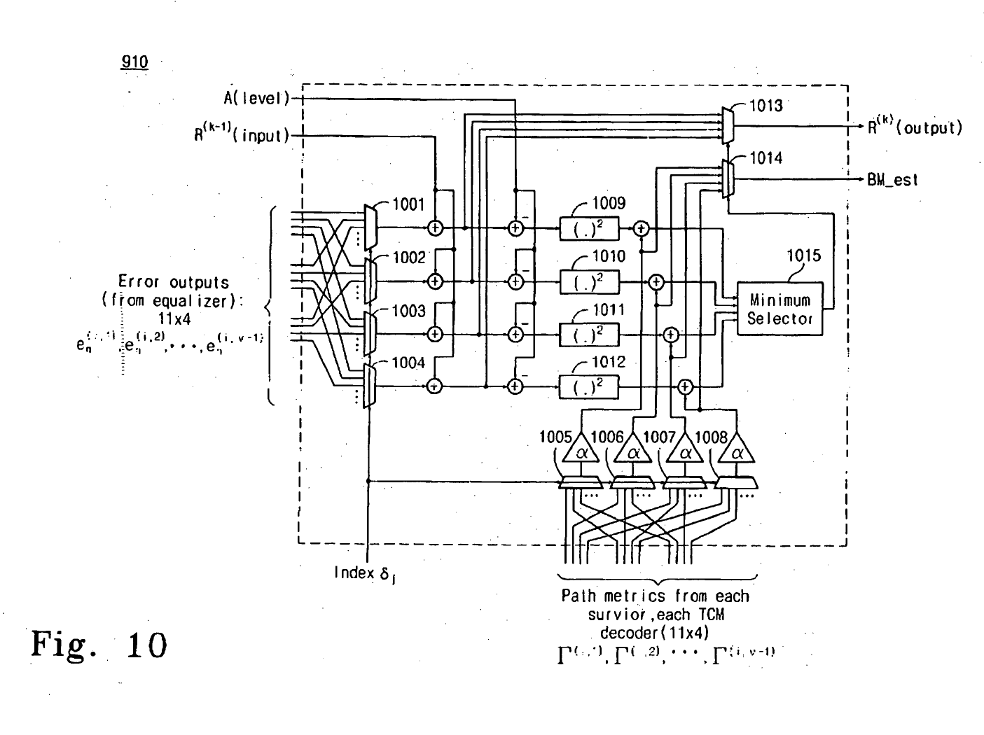

In the example embodiment of FIG. 9, the one-stage BM calculator 910 may receive the reference level A and the initial input signal R(0) from the subset and input selector 900, the error signal e^{(i,k)} from the equalizer feedback part 620, and the surviving path-related path metrics Γ^{(i,k)} from the remaining TCM decoders. The one-state BM calculator 910 may also receive an index value indicating the decoder having a higher (e.g., the highest) ISI intensity value from among the calculated rank information δₖ received from the equalizer feedback part 620. As will be described in greater detail later with respect to FIG. 10, for each rank value among the rank information δ₁, δ₂, δᵥ₋₁, the one-stage BM calculator 910 may then calculate output values as follows
iₘᵢₙ=arg [min {(R^{(k-1)}+eₙ^{(i,δ}^{ₖ}⁾−A)²+αΓ^{(i,δ}^{ₖ}⁾}] Equation 6
R^{(k)}=R^{(k-1)}+αΓn⁽ⁱ^{ₘᵢₙ}^{,δ}^{ₖ}⁾ Equation 7
D^{(k)}=D^{(k-1)}+eₙ⁽ⁱ^{ₘᵢₙ}^{,δ}^{ₖ}⁾ Equation 8

In the example embodiment of FIG. 9, the absolute value squarer 940 may square a difference between the reference value A and a final value R^{(v-1)} outputted after completion of the calculation of the symbol input value and the BM calculation value. The final BM of the TCM decoder 631 may be expressed as the sum of the output of the absolute value squarer 940 and the accumulation value of the BM estimation values BM_est in the respective stages. This may be expressed as
BM=(R^{(v-1)}−A)²+D^{(v-1)} Equation 9

FIG. 10 is a block diagram illustrating the one-stage BM calculator 910 of FIG. 9 according to another example embodiment of the present invention. While FIG. 10 is illustrated and described with respect to the one-stage BM calculator 910, it is understood that that the one-stage BM calculator 910 of FIG. 10 may be representative of any one-stage BM calculator (e.g., 910, 920, 930, etc.).

In the example embodiment of FIG. 10, the one-stage BM calculator 910 may include 12 encoders and 4 states. However, it is understood that these particular numbers of encoders and states are given for example purposes only, and other one-stage BM calculators may include any number of encoders and/or states.

In the example embodiment of FIG. 10, multiplexers 1001˜1004 may each select and output a value corresponding to the rank information δj among error signals about the i-th candidate path. Multiplexers 1005˜1008 may each select a path metric corresponding to the rank information δj among surviving path metrics about the i-th candidate path.

In the example embodiment of FIG. 10, absolute value squarers 1009˜1012 may each calculate a term (R^{(k-1)}+eₙ^{(i,δ}^{ₖ}⁾−A)² (e.g., a portion of Equation 6) which may correspond to a temporary BM value reflecting an error signal.

In the example embodiment of FIG. 10, a minimum selector 1015 may select the minimum value iₘᵢₙ from among values obtained by adding the respective surviving path metrics to the respective temporary BM values.

In the example embodiment of FIG. 10, the multiplexer 1013 may select the symbol estimation value R(k) corresponding to the minimum value iₘᵢₙ, and the multiplexer 1014 may select the BM estimation value BM_est corresponding to the minimum value iₘᵢₙ.

While the example structure of FIG. 10 illustrates one example of implementing Equation 6, it is understood that there are numerous alternative embodiments of structures for implementing Equation 6 which will be readily recognized by one skilled in the art.

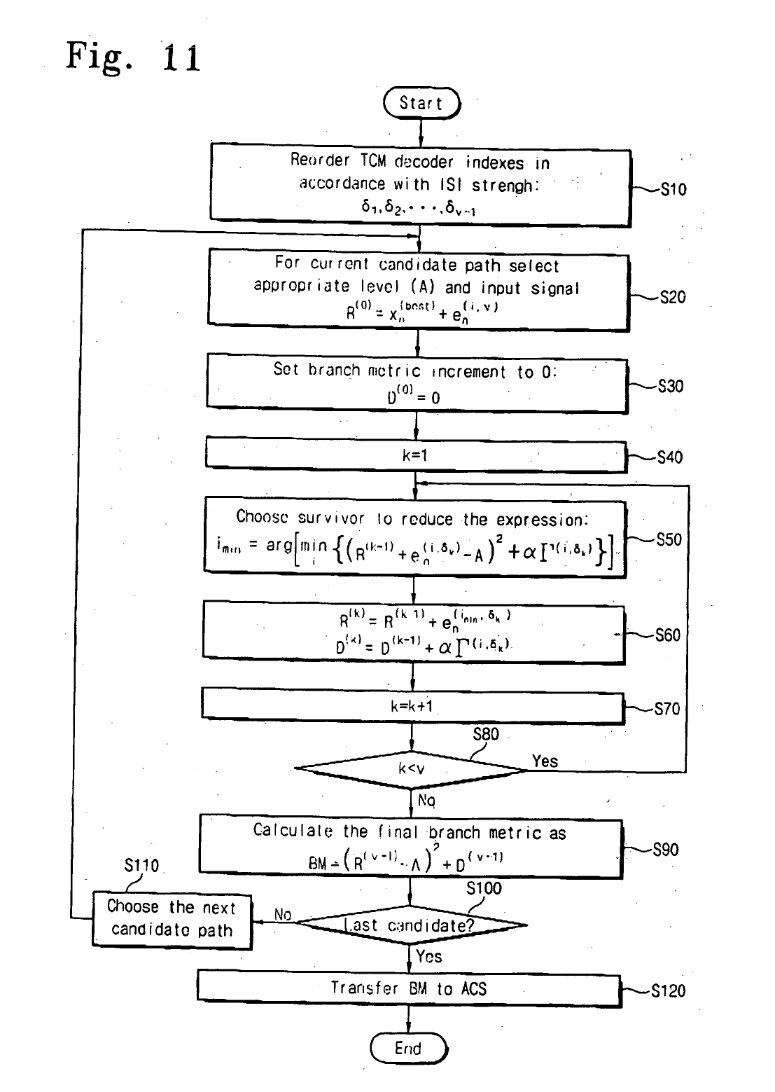

FIG. 11 is a flowchart illustrating a BM calculation process according to another example embodiment of the present invention. In an example, the BM calculation process of FIG. 11 may be performed by the joint TCM decoder 630. Accordingly, hereinafter the process of FIG. 11 will be described with reference to the TCM decoder 630 of FIG. 6. However, it is understood that other hardware may implement the process of FIG. 11 in other example embodiments of the present invention.

In the example embodiment of FIG. 11, the TCM decoder 630 index ranks δ₁, δ₂, . . . , δᵥ₋₁ may be reordered (at S10) in accordance with their respective ISI strengths in order to select a candidate path for which a BM may be calculated. A reference level A for calculating the BM of the selected current candidate path may be selected (at S20). The reference level A may denote a value for calculating an error of a received symbol (input signal: R⁽⁰⁾=xₙ⁽ⁱ⁾=xₙ^{(best)}+eₙ^{(i,v)}) due to a state transition of a trellis diagram.

In the example embodiment of FIG. 11, an increment of the BM may be initialized (at S30). The BM increment may be set to 0 (D⁽⁰⁾=0) and k may be set to 1 (k=1) (at S40). A surviving path i for reducing a metric may be selected (at S50) for each rank δₖ with
iₘᵢₙ=arg [min {(R^{(k-1)}+eₙ^{(i,δ}^{ₖ}⁾−A)²+αΓ^{(i,δ}^{ₖ}⁾}] Equation 10

A received symbol input value and a BM input value may be updated (at S60) using
R^{(k)}=R^{(k-1)}+eₙ⁽ⁱ^{ₘᵢₙ}^{,δ}^{ₖ}⁾
D^{(k)}=D^{(k-1)}+αΓ⁽ⁱ^{ₘᵢₙ}^{,δ}^{ₖ}⁾ Equation 11

In Equations 10 and 11, a coefficient α may denote a normalization coefficient that may be selected for normalizing the path metric. Accordingly, if a state metric Γ^{(i,j)} is not normalized (e.g., at every repeated decoding operation), the normalization coefficient α may reduce the state metric with an increase in the number of repetitions n.

In the example embodiment of FIG. 11, k may be incremented (at S70) and the incremented value of k may be compared with v (e.g., the number of TCM decoders) (at S80). If the comparison (at S80) indicates that k is less than v, the process may return to S20. Otherwise, if the comparison (at S80) indicates that k is equal to or greater than v, the decoder index k may reach v (k=v), and the final BM may be calculated using
BM=(R^{(v-1)}−A)²+D^{(v-1)} Equation 12

After the BM calculation (at S90), the TCM decoder 630 may determine whether a currently selected path is a last path (at S100). If the TCM decoder 630 determines that the currently selected path is not the last path, a next path may be selected (at S110) and the process may return to S20. Otherwise, if the TCM decoder 630 determines that the currently selected path is the last path, the calculated BM (at S90) may be transferred (at S120) to the ACS 820.

In another example embodiment of the present invention, the BM calculation process of FIG. 11 may be above BM calculation algorithm may be implemented in software (e.g., as executable code run by a processing device such as a computer) or via direct hardware implementation. If the number v of the TCM decoders and the number m of the states is relatively small (e.g., below a threshold), the surviving path indexes i₁, i₂, . . . , iᵥ may be alternatively calculated with

$$BM = {min}_{{i}_{1} , {i}_{2} , … , {i}_{v - 1}} \{ {( {R}^{( 0 )} + {\sum }_{k = 1}^{v - 1} {e}_{n}^{( {i}_{k} , k )} - A )}^{2} + α {\sum }_{k = 1}^{v - 1} {Γ}^{( {i}_{k} , k )} \} \qquad Equation 13$$

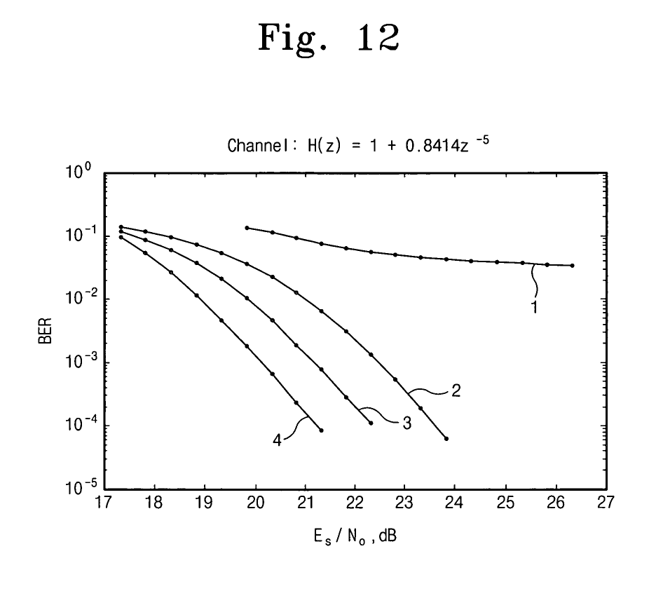

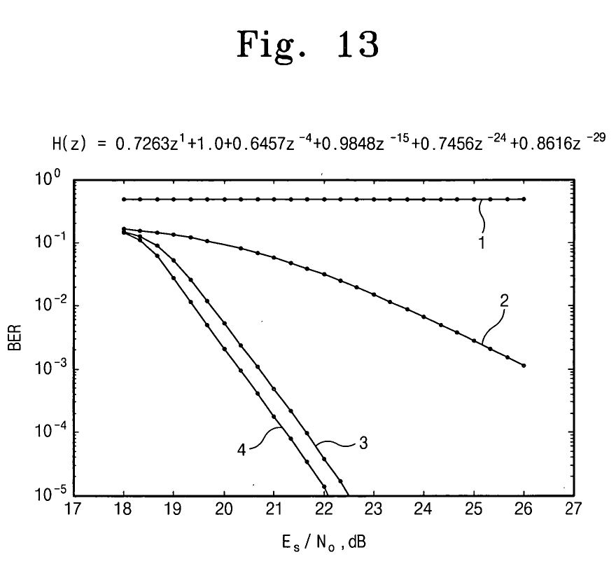

Below, evaluation results are described with respect to FIG. 12 and FIG. 13. With regard to the evaluation results described below and illustrated in FIGS. 12 and 13, it may be assumed that the system being evaluated may be a TDM-TCM system with parameters corresponding to the ATSC D-TV broadcasting standard. It may be further assumed that the number of the interleaved TCM encoders for the inventive decoding system may be 12. While the above-assumptions may be made for the example embodiments of FIGS. 12 and 13, it is understood that other evaluation results may be achieved under different assumptions.

FIG. 12 illustrates a graph of bit error rate (BER) performance (e.g., for a signal-to-noise ratio Es/N0) for a plurality of equalization schemes with respect to a channel having one post-arriving ghost with a 5-symbol delay and an approximately 1.5-dB attenuation, a channel frequency response is given by H(z)=1+0.8414z−5) according to another example embodiment of the present invention.

FIG. 13 illustrates a graph of BER performance (e.g., for Es/N0) for a plurality of equalization schemes with respect to a 6-path channel having one pre-arriving ghost and 4 post-arriving ghosts according to another example embodiment of the present invention. The channel frequency response of the example embodiment of FIG. 13 may be given by H(z)=0.7263z+1+1.0+0.6457z−4+0.984z−15+0.7456z−24+0.8416z−29).

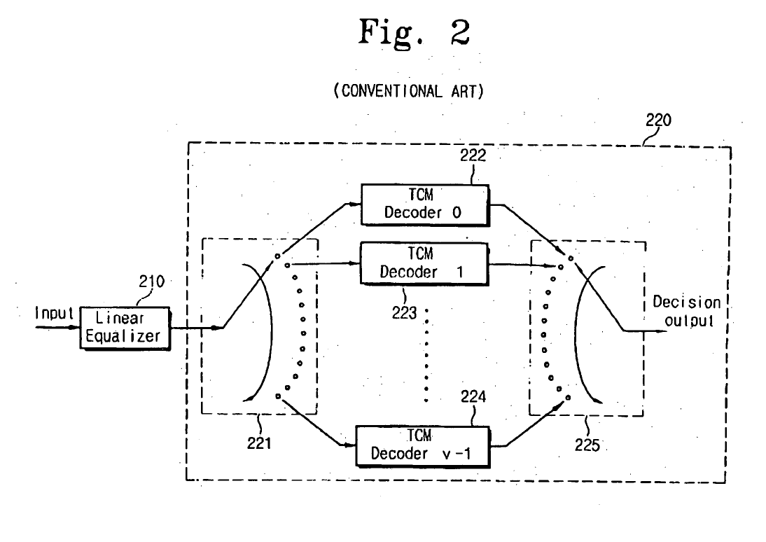

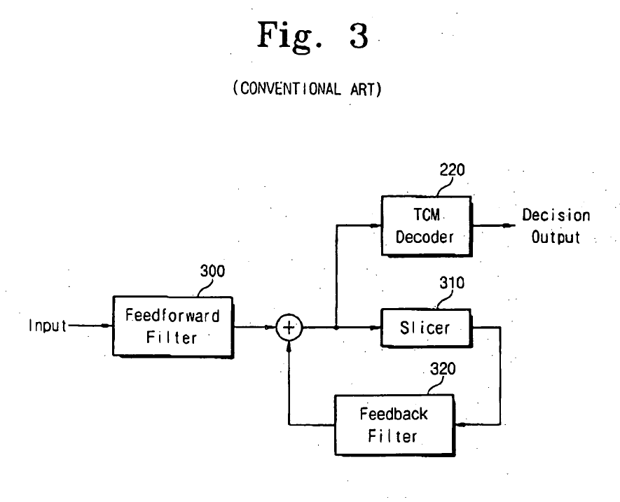

In the example embodiments of FIGS. 12 and 13, the plurality of equalization schemes may each correspond to Curves 1˜4. Curve 1 may represent the performance of the conventional equalization scheme illustrated in FIG. 2 (e.g., a linear equalizer), curve 2 may represent the performance of the conventional equalization scheme illustrated in FIG. 3 (e.g., a DFE using a slicer as a decision device), curve 3 may represent the performance of the conventional equalization scheme illustrated in FIG. 4 (e.g., the DFE using a TCM decoder and a parallel-decision feedback method as a decision device), and curve 4 may represent the performance of an equalization scheme according to another example embodiment of the present invention.

As shown in the example embodiments of FIGS. 12 and 13, under the above assumptions, the equalization scheme according to an example embodiment of the present invention (e.g., using inter-dependent TCM decoders) may achieve an improvement (e.g., in a range of 0.4˜1.1 decibels (dB)) as compared to the conventional equalization scheme of FIG. 4.

In another example embodiment of the present invention, the joint TCM decoder including a plurality of interrelated/interdependent decoders may calculate a branch metric by taking into account path metrics of a plurality of surviving paths, thereby allowing the joint TCM decoder to perform TCM signal decoding with an improved BER (e.g., even in channels having higher ISI).

Example embodiments of the present invention being thus described, it will be obvious that the same may be varied in many ways. For example, while the above-described example embodiments of the present invention are directed generally to TDM-TCM decoders, joint TCM decoders and TCM decoders, it will be appreciated that other example embodiments of the present invention may be directed to any type of decoder. Further, while FIGS. 7 and 9 illustrate three TCM decoders 631/632/633 and one-stage calculators 910/920/930, respectively, it is understood that such illustration is intended for simplicity of presentation, and other example embodiments of the present invention may include any number of TCM decoders and/or one-stage calculators.

Such variations are not to be regarded as departure from the spirit and scope of example embodiments of the present invention, and all such modifications as would be obvious to one skilled in the art are intended to be included within the scope of the following claims.

What is claimed is:

1. An apparatus for decoding a signal, comprising:
an equalizer feedback part generating at least one error signal based on feedback symbol decision values for at least one of a plurality of surviving paths, calculating rank information ranked based at least in part on an interference level, and equalizing a reception signal based at least in part on at least one of the feedback symbol decision values to generate a reception symbol; and
a joint trellis coded modulation (TCM) decoder including a plurality of TCM decoders, at least one of the plurality of TCM decoders calculating a branch metric based on the error signal, the reception symbol, the rank information and an operation of at least one other of the plurality of TCM decoders.

2. The apparatus of claim 1, wherein the received signal is a feedforward filter signal.

3. The apparatus of claim 1, wherein the equalizer feedback part is included within a decision-feedback equalizer (DFE).

4. The apparatus of claim 1, wherein the interference level is a measure of inter-symbol interference (ISI).

5. The apparatus of claim 4, wherein the rank information is used to rank each of the plurality of TCM decoders based on ISI intensity levels.

6. The apparatus of claim 1, wherein one of the plurality of TCM decoders is an active TCM decoder performing a TCM decoding operation based on path metrics including surviving path information associated with at least one inactive TCM decoder among the plurality of TCM decoders, the rank information, the reception symbol, and the error signal.

7. The apparatus of claim 1, wherein each of the plurality of TCM decoders includes
a branch metric unit for generating a branch metric based in part on an operation of the at least one other of the plurality of TCM decoders.
an add-compare-select unit for receiving the branch metric to calculate a path metric; and
a trace-back unit for tracing back from a smallest state of the path metric to output a path metric corresponding to a survivor path and a decoded symbol according to a most probable survivor path.

8. The apparatus of claim 7, wherein at least one of the branch metric units includes:
a reference level selection circuit for receiving the reception symbol and the error signal to select a reference level (A) corresponding to the reception symbol and generate an initial input signal (R⁽⁰⁾); and
a branch metric calculation circuit for calculating a branch metric with reference to the initial input signal, the reference level, the error signal, and path metrics for surviving paths from the at least one other of the plurality of TCM decoders.

9. The apparatus of claim 8, wherein at least one of the branch metric calculation circuits includes serially-connected branch metric cells having a number based on the number of the plurality of TCM decoders, each of the branch metric cells calculating a branch metric estimation value with reference to a surviving path value of a corresponding one of the plurality of other TCM decoders.

10. The apparatus of claim 9, wherein at least one of the branch metric calculation circuits implements a process satisfying BM=(R^{(v-1)}−A)²+D^{(v-1)}
wherein BM is a final branch metric, R^{(v-1)} is a final symbol estimation value, A is a reference level, and D^{(v-1)} is an accumulation value of branch metric estimation values (BM_est) from the branch metric cells of one of the branch metric units.

11. The apparatus of claim 10, wherein the at least one other branch metric unit obtains a surviving path index (iₘᵢₙ) satisfying
iₘᵢₙ=arg [min {(R^{(k-1)}+eₙ^{(i,δ}^{ₖ}⁾−A)²+αΓ^{(i,δ}^{ₖ}⁾}]
wherein R^{(k-1)} is a symbol estimation value from a previous branch metric cell, eₙ^{(i,δ}^{ₖ}⁾ is an error signal, A is a reference level, α is a positive coefficient for normalizing path metrics, and Γ^{(i,δ}^{ₖ}⁾ are surviving path metrics, the at least one other branch metric unit satisfying R^{(k)}=R^{(k-1)}+eₙ⁽ⁱ^{ₘᵢₙ}^{,δ}^{ₖ}⁾ and D^{(k)}=D^{(k-1)}+αΓ⁽ⁱ^{ₘᵢₙ}^{,δ}^{ₖ}⁾.

12. The apparatus of claim 1, wherein the equalizer feedback part performs an adaptive equalization operation on the reception signal.

13. The apparatus of claim 1, further comprising:
a feedforward filter connected to an input port of the equalizer feedback part.

14. The apparatus of claim 1, wherein the equalizer feedback part uses a parallel-decision feedback scheme.

15. The apparatus of claim 1, wherein the plurality of TCM decoders are connected in parallel and the joint TCM decoder demultiplexes the reception symbol.

16. The apparatus of claim 1, wherein the error signal for the reception symbol correspond to m×v signals obtained by
$${e}_{n}^{( i , k )} = {\sum }_{t = 0}^{{}^{*} K / v +} {b}_{N + k} ( {d}_{n - tv - k}^{i} - {d}_{n - tv - k}^{( best )} ) ;$$
$$( k = 1 , 2 , … , v , i = 0 , 1 , … , m - 1 )$$
wherein *K/v+ represents a maximum integer not exceeding K/v, v is the number of the plurality of TCM decoders, m is the number of states, d⁽ⁱ⁾ is a decision value by the i-th surviving path, d^{(best)} is a decision value by the most probable path among surviving paths, and bₖ is an equalizer tap coefficient.

17. The apparatus of claim 7, wherein at least one of the branch metric calculation circuits implements an algorithm corresponding to
$$BM = {min}_{{i}_{1} , {i}_{2} , … , {i}_{v - 1}} \{ {( {R}^{( 0 )} + {\sum }_{k = 1}^{v - 1} {e}_{n}^{( {i}_{k} , k )} - A )}^{2} + α {\sum }_{k = 1}^{v - 1} {Γ}^{( {i}_{k} , k )} \}$$
wherein BM is a final branch metric, and i₁, i₂, . . . , iᵥ₋₁ are surviving path indexes.

18. A method for decoding a signal, comprising:
equalizing a reception signal to generate a reception symbol based on decision data associated with a previous reception symbol;
calculating error signals associated with the decision data based on a most probable surviving path of the previous symbol and decision data associated with remaining surviving paths; and
calculating branch metrics based on the reception symbol, the error signals, rank information associated with a plurality of trellis coded modulation (TCM) decoders, and path metrics for each of the plurality of TCM decoders.

19. The method of claim 18, wherein the rank information associated with the plurality of TCM decoders is calculated based on an inter-symbol interference (ISI) intensity.

20. The method of claim 18, wherein calculating the branch metrics includes an add-compare-select operation for updating a current path metric to the minimum path metric by adding a path metric of a previous stage to the current path metric; and
a trace back operation for tracing back the minimum path metric to output decision data.

21. The method of claim 18, wherein the reception symbol is calculated by
$${x}_{n}^{( best )} = {r}_{n} + {\sum }_{j = 1}^{K} {b}_{j} {d}_{n - j}^{( best )}$$
wherein rⁿ is a feedforward filter output signal for the n-th symbol, bⱼ are feedback filter tap coefficients, and d^{(best)} is a symbol decision value corresponding to the best surviving path of the TCM decoder with respect to the previous symbol.

22. The method of claim 18, wherein the error signals correspond to m×v signals calculated by
$${e}_{n}^{( i , k )} = {\sum }_{t = 0}^{{}^{*} K / v +} {b}_{N + k} ( {d}_{n - tv - k}^{i} - {d}_{n - tv - k}^{( best )} ) ;$$
$$( k = 1 , 2 , … , v , i = 0 , 1 , … , m - 1 )$$
where bⱼ are feedback filter tap coefficients, d^{(best)} is a symbol decision value corresponding to the best surviving path of the TCM decoder with respect to the previous symbol, *K/v+ represents the maximum integer not exceeding K/v, d⁽ⁱ⁾ is a symbol decision value associated with the surviving paths for the previous symbol, v is the number of the TCM decoders, and m is the number of states.

23. The method of claim 19, wherein calculating the branch metrics includes determining a rank order δ₁, δ₂, . . . δᵥ₋₁ of the plurality of TCM decoders based on the ISI intensity;
selecting a candidate path on which a branch metric is to be calculated;
selecting a reference level A corresponding to a state transition of a trellis diagram with respect to the candidate path, calculating a symbol estimation initial value R⁽⁰⁾ by adding the error signal eₙ^{(i,v)} and the previous main equalizer output signal xₙ^{(best)} for the candidate path, and initializing an initial branch metric increment D⁽⁰⁾ to 0;
repeatedly updating a branch metric estimation value D^{(k)} and a symbol estimation value R^{(k)} satisfying
iₘᵢₙ=arg [min {(R^{(k-1)}+eₙ^{(i,δ}^{ₖ}⁾−A)²+αΓ^{(i,δ}^{ₖ}⁾}]
R^{(k)}=R^{(k-1)}+eₙ⁽ⁱ^{ₘᵢₙ}^{,δ}^{ₖ}⁾
D^{(k)}=D^{(k-1)}+αΓ⁽ⁱ^{ₘᵢₙ}^{,δ}^{ₖ}⁾
wherein R^{(k-1)} is a symbol metric estimation value, eₙ^{(i,δ}^{ₖ}⁾ are error signals, α is a positive coefficient for normalizing path metrics, and Γ^{(i,δ}^{ₖ}⁾ are surviving path metrics; and
calculating a branch metric for the candidate path by the final symbol estimation value R^{(v-1)} and a branch metric accumulation value D^{(v-1)} to satisfy
BM=(R^{(v-1)}−A)²+D^{(v-1)}
wherein A is a reference level.

24. The method of claim 23, further comprising:
repeating the above steps of calculating the branch metrics for at least one other candidate path.

25. The method of claim 18, wherein calculating the branch metrics is performed on each of surviving path indexes i₁, i₂, . . . , iᵥ₋₁ so as to satisfy
$$BM = {min}_{{i}_{1} , {i}_{2} , … , {i}_{v - 1}} \{ {( {R}^{( 0 )} + {\sum }_{k = 1}^{v - 1} {e}_{n}^{( {i}_{k} , k )} - A )}^{2} + α {\sum }_{k = 1}^{v - 1} {Γ}^{( {i}_{k} , k )} \}$$
wherein BM is a final branch metric, eₙ^{(i,k)} is an error signal, R⁽⁰⁾ is a symbol metric estimation value, A is a reference level, α is a normalization coefficient of a path metric and Γ^{(i,δ}^{ₖ}⁾ are surviving path metrics.

26. A method for decoding a signal, comprising:
calculating a main equalizer output signal and an error signal based on a reception signal and a decision value of a previous reception symbol; and
calculating branch metrics of an active trellis coded modulation (TCM) decoder based on the main equalizer output signal, the error signal, and path metrics associated surviving paths of a plurality of inactive TCM decoders.

27. The method of claim 26, wherein calculating the branch metrics includes
determining a rank order δ₁, δ₂, . . . , δᵥ₋₁ of a plurality of TCM decoders based on an inter-symbol interference (ISI) intensity, the plurality of TCM decoders including the active TCM decoder and the plurality of inactive TCM decoders;
selecting a candidate path on which a branch metric is to be calculated;
selecting a reference level A corresponding to a state transition of a trellis diagram with respect to the candidate path, calculating a symbol estimation initial value R⁽⁰⁾ by adding the error signal eₙ^{(i,v)} and a previous main equalizer output signal xₙ^{(best)} for the candidate path, and initializing an initial branch metric increment D⁽⁰⁾ to 0;
repeatedly updating a branch metric estimation value D^{(k)} and a symbol estimation value R^{(k)} satisfying
iₘᵢₙ=arg [min {(R^{(k-1)}+eₙ^{(i,δ}^{ₖ}⁾A)²+αΓ^{(i,δ}^{ₖ}⁾}]
R^{(k)}=R^{(k-1)}+eₙ⁽ⁱ^{ₘᵢₙ}^{,δ}^{ₖ}⁾
D^{(k)}=D^{(k-1)}+αΓ⁽ⁱ^{ₘᵢₙ}^{,δ}^{ₖ}⁾
wherein R^{(k-1)} is a symbol metric estimation value, eₙ^{(i,δ}^{ₖ}⁾ are error signals, α is a positive coefficient for normalizing path metrics, and Γ^{(i,δ}^{ₖ}⁾ are surviving path metrics; and
calculating a branch metric for the candidate path by the final symbol estimation value R^{(v-1)} and a branch metric accumulation value D^{(v-1)} to satisfy
BM=(R^{(v-1)}−A)²+D^{(v-1)}
wherein A is a reference level.

28. The method of claim 27, further comprising:
repeating the above steps of calculating the branch metrics for at least one other the candidate path.

29. The method of claim 26, wherein calculating the branch metrics is performed on each of surviving path indexes i₁, i₂, . . . , iᵥ₋₁ so as to satisfy
$$BM = {min}_{{i}_{1} , {i}_{2} , … , {i}_{v - 1}} \{ {( {R}^{( 0 )} + {\sum }_{k = 1}^{v - 1} {e}_{n}^{( {i}_{k} , k )} - A )}^{2} + α {\sum }_{k = 1}^{v - 1} {Γ}^{( {i}_{k} , k )} \}$$
wherein BM is a final branch metric, eₙ^{(i,k)} is an error signal, R⁽⁰⁾ is a symbol metric estimation value, A is a reference level, α is a normalization coefficient of a path metric and Γ^{(i,δ}^{ₖ}⁾ are surviving path metrics.

30. A method of branch metric calculation, comprising:
calculating a branch metric based at least in part on a plurality of received path metrics.

31. The method of claim 30, wherein calculating the branch metric is performed at a first trellis coded modulation (TCM) decoder and the plurality of received path metrics are received from a plurality of TCM decoders other than the first TCM decoder.

32. The method of claim 30, further comprising:
calculating a resultant path metric based on the calculated branch metric.

33. The method of claim 32, further comprising:
outputting the resultant path metric to a plurality of TCM decoders.

34. A trellis coded modulation (TCM) decoder, comprising:
a branch metric unit calculating a branch metric based at least in part on a received plurality of path metrics.

35. The TCM decoder of claim 34, further comprising:
an add-compare-select (ACS) unit combining the calculated branch metric with a cumulative path metric to form a resultant path metric; and
a trace-back unit outputting the resultant path metric.

36. A joint TCM decoder including a plurality of TCM decoders, at least one of the plurality of TCM decoders configured according to claim 34.

37. The joint TCM decoder of claim 36, wherein the trace-back unit outputs the resultant path metric to branch metric units at each of the plurality of TCM decoders.

38. The joint TCM decoder of claim 36, wherein the received plurality of path metrics include resultant path metrics received from trace-back units at each of the plurality of TCM decoders.

39. The joint TCM decoder of claim 36, wherein the joint TCM decoder is included within a time-division multiplexed trellis-coded modulation (TDM-TCM) decoder.
